(19) United States
(12) Patent Application Publication
(10) Pub. No.: US 2024/0222142 A1
(43) Pub. Date: Jul. 4, 2024

(54) EFFICIENT AUTOCATALYTIC METALLIZATION OF POLYMERIC SURFACES

(71) Applicant: Applied Materials, Inc., Santa Clara, CA (US)

(72) Inventors: Tapash CHAKRABORTY, Thane (IN); Steven VERHAVERBEKE, San Francisco, CA (US); Han-Wen CHEN, Cupertino, CA (US); Kyuil CHO, Santa Clara, CA (US); Kent ZHAO, San Francisco, CA (US); Gopi Chandran RAMACHANDRAN, Mumbai (IN)

(21) Appl. No.: 18/089,632

(22) Filed: Dec. 28, 2022

(51) Int. Cl. H01L 21/48; H01L 23/538; H10B 80/00

(52) U.S. Cl. CPC H01L 21/486; H01L 23/5384; H01L 23/5389; H10B 80/00

(57) ABSTRACT

Semiconductor packages and methods for metallization of non-conducting surfaces for fabricating semiconductor packages are provided. In an embodiment, the method includes depositing an adhesion layer on a polymeric surface by an electroless deposition process. The polymeric surface defines a sidewall of a through-hole via and the adhesion layer comprises a cobalt alloy or a nickel alloy. The method further includes depositing a copper seed layer on the adhesion layer by an immersion plating process. The copper seed layer displaces a portion of the adhesion layer. The method further includes filling the through-hole via with a copper containing layer.

### BACKGROUND

### Field

The disclosure generally relates to semiconductor packaging and methods of fabricating semiconductor packages. More particularly, the disclosure relates to metallization of non-conducting surfaces for fabricating semiconductor packages.

### Description of the Related Art

Electronic packaging and assembly are typically used to link the small dimensions of an integrated circuit (IC) to an interconnecting substrate, for example, a printed circuit board (PCB). The PCB usually includes a number of passive components and ICs to build a microelectronic device. As the semiconductor industry has experienced rapid growth due to ongoing improvements in the integration density of a variety of electronic components, for example, transistors, diodes, resistors, and capacitors. For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

For the foregoing reasons, there is a need for improved semiconductor packaging and methods of fabricating semiconductor packages.

### SUMMARY

In one aspect, a method of manufacturing a semiconductor device is provided. The method includes depositing an adhesion layer on a polymeric surface by an electroless deposition process. The polymeric surface defines a sidewall of a through-hole via and the adhesion layer comprises a cobalt alloy or a nickel alloy. The method further includes depositing a copper seed layer on the adhesion layer by an immersion plating process. The copper seed layer displaces a portion of the adhesion layer. The method further includes filling the through-hole via with a copper containing layer.

Implementations may include one or more of the following. The polymeric surface is exposed to a heat treatment process prior to depositing the adhesion layer, wherein the heat treatment process comprises exposing the polymeric surface to heat at a temperature in a range from about 100 degrees Celsius to about 150 degrees Celsius. The polymeric surface is exposed to an activation process prior to the heat treatment process, including exposing the polymeric surface to a first bath comprising hydrochloric acid and sodium chloride, exposing the polymeric surface to a catalyst bath comprising hydrochloric acid, tin chloride, and palladium chloride, and exposing the polymeric surface to fluoboric acid. The electroless deposition process includes exposing the polymeric surface to an electroless deposition solution comprising aqueous nickel sulfate solution, an aqueous sodium hypophosphite solution, and water. The electroless deposition solution is heated to a temperature in a range from about 80 degrees Celsius to about 90 degrees Celsius. The portion of the adhesion layer that is replaced by the copper seed layer is about 10 to about 30% of the original thickness of the adhesion layer. The adhesion layer includes NiP, NiWP, CoP, or CoWP. The polymeric surface includes polybenzoxazole (PBO), polyimide, a polyimide derivative, an epoxy resin, a prepreg (PP) material, or a combination thereof.

In another aspect, a method of manufacturing a semiconductor device is provided. The method includes providing a substrate comprising an insulating material, the insulating material defining a first major surface, a second major surface opposite the first major surface, and a through-hole via coupling the first major surface and the second major surface. The method further includes depositing an adhesion layer on the insulating material by an electroless deposition process. The insulating material defines a sidewall of the through-hole via and the adhesion layer comprises a cobalt alloy or a nickel alloy. The method further includes depositing a copper seed layer on the adhesion layer by an immersion plating process. The copper seed layer displaces a portion of the adhesion layer. The method further includes forming a photoresist layer on the copper seed layer formed over at least the first major surface. The photoresist is patterned to form an opening through the photoresist layer. The opening exposes the copper seed layer formed along the sidewall of the through-hole vias. The through-hole via and the opening are filled with a copper containing layer to form an interconnect structure. The photoresist is removed to expose the adhesion layer and the copper seed layer formed over at least the first major surface.

Implementations may include one or more of the following. The adhesion layer and the copper seed layer are removed from the first major surface by an etching process, wherein the etching process removes the copper seed layer and the adhesion layer at a greater rate than the copper of the interconnect structure. The etching process includes exposing the adhesion layer and the copper seed layer to an etchant solution comprising copper sulfate and sulfuric acid. The etching process includes exposing the adhesion layer and the copper seed layer to an etchant solution comprising from about 0.5 M to about 1.5 M CuSO₄·5H₂O and from about 0.02 M to 2 M H₂SO₄. The polymeric surface is exposed to a heat treatment process prior to depositing the adhesion layer, wherein the heat treatment process comprises exposing the polymeric surface to heat at a temperature in a range from about 100 degrees Celsius to about 150 degrees Celsius. The polymeric surface is exposed to an activation process prior to the heat treatment process, the activation process includes exposing the polymeric surface to a first bath comprising hydrochloric acid and sodium chloride, exposing the polymeric surface to a catalyst bath comprising hydrochloric acid, tin chloride, and palladium chloride, and exposing the polymeric surface to fluoboric acid.

In yet another aspect, a semiconductor device is provided. The device includes a substrate comprising an insulating material, the insulating material defining a first major surface, a second major surface opposite the first major surface, and a through-hole via coupling the first major surface and the second major surface. The device further includes an adhesion layer formed on the insulating material defining a sidewall of the through-hole via, the adhesion layer comprising a cobalt alloy or a nickel alloy. The device further includes a copper seed layer formed on the adhesion layer. The device further includes a copper interconnection extending the entire thickness of the substrate, the copper interconnection filling the through-hole via and extending passed both the first major surface and the second major surface.

Implementations may include one or more of the following. The adhesion layer comprises NiP, NIWP, CoP, or CoWP. The polymeric surface includes polybenzoxazole (PBO), polyimide, a polyimide derivative, an epoxy resin, a prepreg (PP) material, or a combination thereof. The substrate further includes a semiconductor die encapsulated by the insulating material. The substrate is part of a three-dimensional multichip module.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A illustrates a schematic view of a three-dimensional multichip module (3-D MCM) in accordance with one or more implementations.

FIG. 1B illustrates a schematic view of a 3-D MCM in accordance with one or more implementations.

FIG. 2 illustrates an exemplary flow chart of a method for metallization of a polymeric surface in accordance with one or more implementations of the present disclosure.

FIGS. 3A-3D illustrate cross-sectional views of various stages of metallization of a polymeric surface in accordance with one or more implementations of the present disclosure.

FIG. 4 illustrates an exemplary flow chart of a method of forming a 3-D MCM structure in accordance with one or more implementations of the present disclosure.

FIGS. 5A-5I illustrate cross-sectional views of various stages of forming a 3-D MCM structure in accordance with one or more implementations of the present disclosure.

To facilitate understanding, identical reference numerals have been used, where possible, to designate identical elements that are common to the figures. It is contemplated that elements and features of one implementation may be beneficially incorporated in other embodiments without further recitation.

### DETAILED DESCRIPTION

The disclosure generally relates to semiconductor packaging and methods of fabricating semiconductor packages. More particularly, the disclosure relates to metallization of non-conducting surfaces for fabricating semiconductor packages. Metallization of non-conducting surfaces, for example, electroless deposition of copper on a polymer surface currently involves a nine-step process including multiple wet chemistry baths. This nine-step process includes pretreatment steps such as desmear, oxidation, neutralization, and conditioning with corrosive chemicals, which renders the non-conducting surface rough by making the non-conducting surface microporous to improve adhesion. However, the roughness achieved using the nine-step process can limit the ability to scale down. In addition, the current nine-step process is time consuming and costly.

Various aspects described provide an efficient process involving fewer steps to metallize a non-conducting surface of interest in the area of advanced packaging. The process is better in terms of performance like lower roughness compared to the current nine-step process. The lower roughness allows scaling packaging. In at least one implementation, a non-conducting surface is metallized by depositing an electroless alloy layer, which functions as an adhesion layer, followed by an immersion (displacement) plating process to form a thin seed layer on the adhesion layer. The adhesion layer includes a nickel or cobalt alloy, for example, NiP, NiWP, CoP, or CoWP. The immersion plating process deposits a copper coating on the adhesion layer from a solution that contains copper. One metal in the adhesion layer is displaced by a copper ion that has a lower oxidation potential than the displaced metal ion. Once the seed layer is formed an interconnect structure may be formed in a feature, for example, a through-hole via, using an electroplating or electroless plating process. The electroless nickel or cobalt alloy can be formed on the non-conducting surface without using corrosive pretreatments to roughen the non-conducting surface. In addition, the immersion copper seed layer formed on the electroless alloy is much less rough. Thus, improved results can be achieved in fewer steps.

Various aspects described further provide a wet chemical, controlled etch of metal stack, for example, the adhesion layer/seed layer stack described, useful for patterning for advanced packaging interconnects. For interconnect patterning in the packaging domain there is a need for controlled removal of a thin layer of copper along with an underlying thicker nickel or cobalt alloy used as a metallization layer as described. This removal is against a thicker, adjacent copper layer, for example, the interconnect structure. Current etchants are either too fast for copper or do not remove enough. In at least one implementation, the composition of an etchant and optimized process conditions are provided. The etchant and process conditions can etch copper as well as nickel or cobalt alloys in a controlled manner.

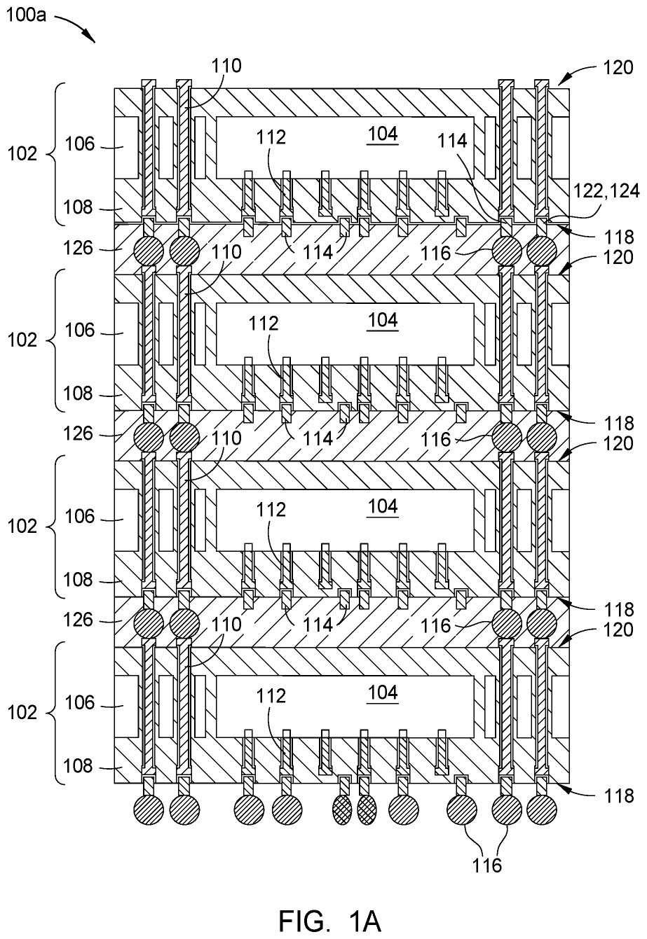

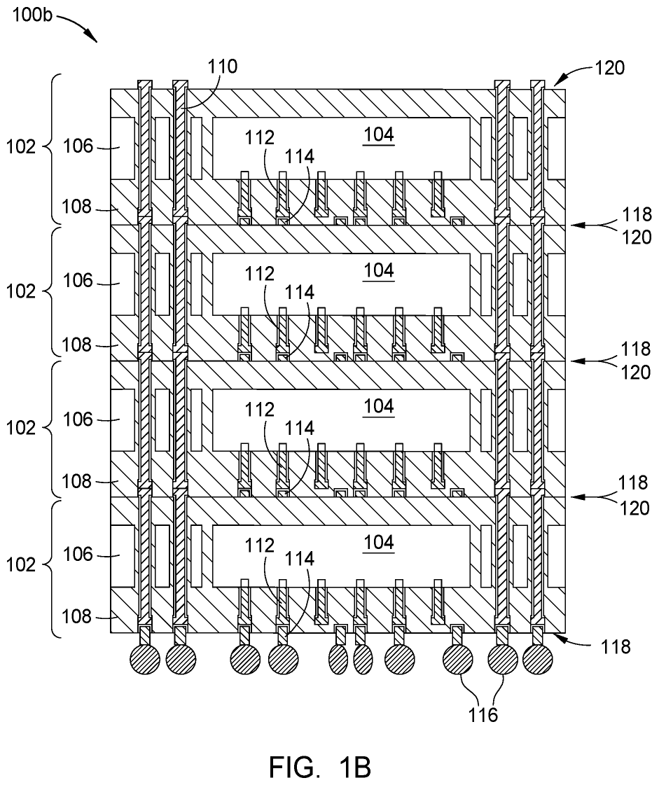

FIG. 1A illustrates a schematic view of a 3-D MCM 100a in accordance with one or more implementations. In at least one implementation, as shown in FIG. 1A, the 3-D MCM 100a is formed of four semiconductor packages 102. Each semiconductor package 102 includes a semiconductor die 104, for example, a memory chip, embedded within a substrate 106 and encapsulated by an insulating material 108, for example, having a portion of each side in contact with the insulating material 108. In at least one implementation, the insulating material 108 is formed by curing a ceramic-filler-containing epoxy resin, such as an epoxy resin containing silica (SiO₂) particles. Other examples of ceramic fillers that may be utilized to form the insulating material 108 include aluminum nitride (AlN), aluminum oxide (Al₂O₃), silicon carbide (SiC), silicon nitride (Si₃N₄), Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. The insulating material 108 may be a polymer layer such as polybenzoxazole (PBO), although any suitable material, such as polyimide, or a polyimide derivative, an epoxy resin, a prepreg (PP) material such as gall fiber, resin, and fillers, an Ajinomoto Build-up Film® (ABF) (e.g., epoxy with silica fillers), polyethylene terephthalate (PET), or combinations thereof. In one example, the insulating material 108 is formed from ABF. In some examples, the ceramic fillers utilized to form the insulating material 108 have particles ranging in size from about 40 nm to about 1.5 μm, or ranging in size from about 80 nm to about 1 μm, or ranging in size from about 300 nm to about 600 nm. In at least one implementation, the ceramic fillers utilized to form the insulating material 108 include particles having a size less than about 25% of the targeted feature, for example, via, cavity, or through-assembly via, width or diameter, such as less than about 15% of the targeted feature width or diameter. One or more interconnections 110 are formed though the entire thickness of each semiconductor package 102. One or more interconnections 112 are formed through the insulating material 108. In at least one implementation, one or more redistribution connections 114 are formed in the semiconductor package 102 to relocate contact points of the interconnections to targeted lateral locations on the surface of the semiconductor package 102.

The interconnections 110 are in contact with one or more solder bumps 116 disposed between major surfaces 118 and 120 of adjacent the semiconductor packages directly, or via the redistribution connections 114 or an optional adhesion layer 122 and/or seed layer 124 formed on the insulating material 108. The redistribution connections 114 are formed by any suitable methods including electroplating and electroless deposition. In at least one implementation, the adhesion layer 122 is formed from titanium, titanium nitride, tantalum, tantalum nitride, manganese, manganese oxide, molybdenum, cobalt oxide, cobalt nitride, or any other suitable materials or combinations thereof. In at least one implementation, the adhesion layer 122 has a thickness of between about 10 nm and about 300 nm, such as between about 50 nm and about 150 nm. For example, the adhesion layer 122 has a thickness between about 75 nm and about 125 nm, such as about 100 nm. The adhesion layer 122 may be formed by any suitable deposition process, including but not limited to CVD, PVD, PECVD, ALD, or the like. The seed layer 124 is formed of a conductive material such as copper, tungsten, aluminum, silver, gold, or any other suitable materials or combinations thereof. In at least one implementation, the seed layer 124 has a thickness between about 50 nm and about 500 nm, such as between about 100 nm and about 300 nm. For example, the seed layer 124 has a thickness between about 150 nm and about 250 nm, such as about 200 nm. In at least one implementation, the seed layer 124 has a thickness in a range from about 0.1 μm to about 1.5 μm. Similar to the adhesion layer 122, the seed layer 124 is formed by any suitable deposition process, such as CVD, PVD, PECVD, ALD dry processes, wet electroless plating processes, or the like. In at least one implementation, the adhesion layer 122 is a molybdenum adhesion layer formed on the semiconductor die 104 in combination with the seed layer 124, which is a copper seed layer.

As depicted in the 3-D MCM 100a, four or more solder bumps 116 are disposed between major surfaces 118 and 120 of adjacent semiconductor packages 102 to bridge, for example, connect or couple, the interconnections 110 of each semiconductor package 102 with the interconnections 110 of an adjacent semiconductor package 102.

In at least one implementation, voids between adjacent semiconductor packages 102 connected by the solder bumps 116 are filled with an encapsulation material 126 to enhance the reliability of the solder bumps 116. The encapsulation material 126 may be any suitable type of encapsulant or underfill. In one example, the encapsulation material 126 includes a pre-assembly underfill material, such as a no-flow underfill (NUF) material, a nonconductive paste (NCP) material, and a nonconductive film (NCF) material. In one example, the encapsulation material 126 includes a post-assembly underfill material, such as a capillary underfill (CUF) material and a molded underfill (MUF) material. In at least one implementation, the encapsulation material 126 includes a low-expansion-filler-containing resin, such as an epoxy resin filled with, for example, containing SiO₂, AlN, Al₂O₃, SiC, Si₃N₄, Sr₂Ce₂Ti₅O₁₆, ZrSiO₄, CaSiO₃, BeO, CeO₂, BN, CaCu₃Ti₄O₁₂, MgO, TiO₂, ZnO, and the like.

In at least one implementation, the solder bumps 116 are formed of one or more intermetallic compounds, such as a combination of tin (Sn) and lead (Pb), silver (Ag), Cu, or any other suitable metals thereof. For example, the solder bumps 116 are formed of a solder alloy such as Sn—Pb, Sn—Ag, Sn—Cu, or any other suitable materials or combinations thereof. In at least one implementation, the solder bumps 116 include C4 (controlled collapse chip connection) bumps. In at least one implementation, the solder bumps 116 include C2 (chip connection, such as a Cu-pillar with a solder cap) bumps. Utilization of C2 solder bumps enables a smaller pitch between contact pads and improved thermal and/or electrical properties for the 3-D MCM 100a. In at least one implementation, the solder bumps 116 have a diameter between about 10 μm and about 150 μm, such as a diameter between about 50 μm and about 100 μm. The solder bumps 116 may further be formed by any suitable wafer bumping processes, including but not limited to electrochemical deposition (ECD) and electroplating.

FIG. 1B illustrates a schematic view of a 3-D MCM structure 100b in accordance with one or more implementations. The 3-D MCM structure 100b that is formed by stacking four semiconductor packages 102 and directly bonding one or more interconnections 110 of each semiconductor package 102 with the interconnections 110 of one or more adjacent semiconductor packages 102. As depicted, the semiconductor packages 102 may be bonded by hybrid bonding, in which major surfaces 118 and 120 of adjacent packages are planarized and in full contact with each other. Thus, one or more interconnections 110 of each semiconductor package 102 are formed through the entire thickness of each semiconductor package 102 and are in contact with one or more interconnections 112 of at least another adjacent semiconductor package 102.

The formation of the one or more interconnections 110 and the one or more interconnections 112 is described.

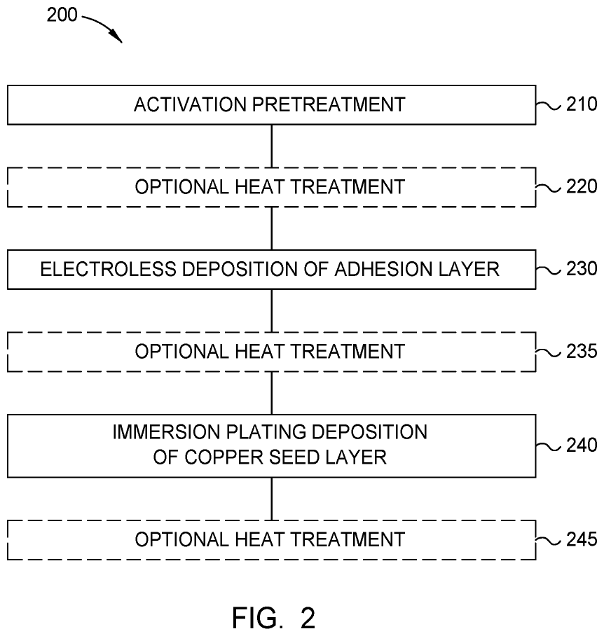

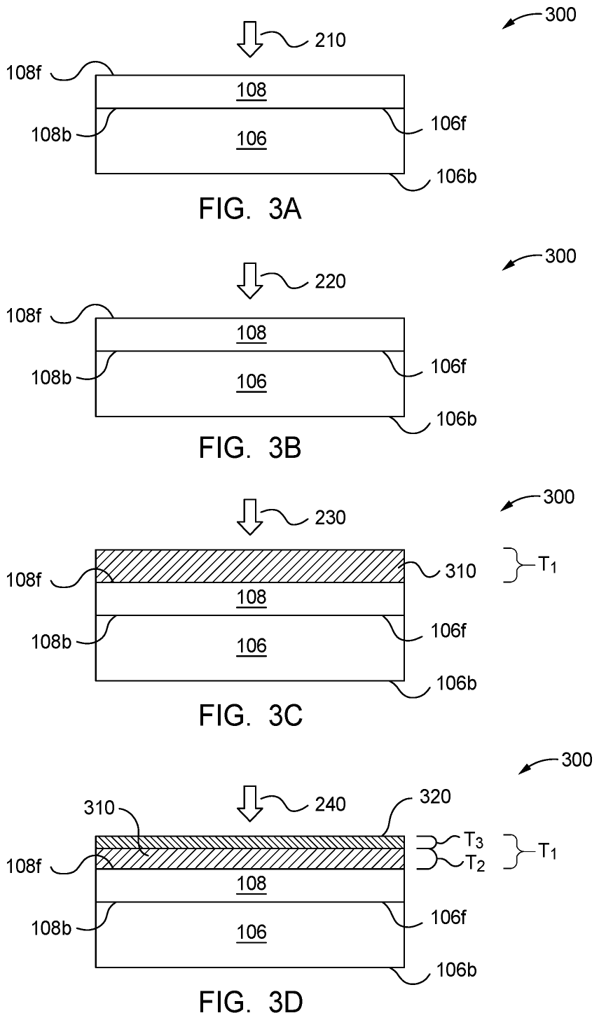

FIG. 2 illustrates an exemplary flow chart of a method 200 for metallization of a polymeric surface in accordance with one or more implementations of the present disclosure. The method 200 may be used for forming an advanced packaging structure, for example, a 3-D MCM as described. FIGS. 3A-3D illustrate cross-sectional views of various stages of metallization of a polymeric surface in accordance with one or more implementations of the present disclosure. Although FIGS. 3A-3D are described in relation to the method 200, it will be appreciated that the structure disclosed in FIGS. 3A-3D are not limited to the method 200, but instead may stand alone as structures independent of the method 200. Similarly, although the method 200 is described in relation to FIGS. 3A-3D, it will be appreciated that the method 200 is not limited to the structures disclosed in FIGS. 3A-3D, but instead may stand alone independent of the structures disclosed in FIGS. 3A-3D.

FIG. 3A illustrates a cross-sectional view of a portion of a structure 300, for example, the 3-D MCM structure 100a, 100b, during intermediate stages of manufacturing corresponding to operation 210, in accordance with some implementations. The structure 300 includes the substrate 106 having the insulating material 108 formed thereon. The substrate 106 includes a frontside 106f (also referred to as a front surface) and a backside 106b opposite the frontside 106f. The insulating material 108 is formed on the frontside 106f of the substrate 106. The insulating material 108 includes a polymeric surface 108f (also referred to as a frontside) and a backside 108b opposite the polymeric surface 108f. Although FIG. 3A shows the insulating material 108 formed on the substrate 106, the method 200 may be performed on the insulating material 108 without the presences of the substrate 106.

During operation 210, an activation pretreatment process is performed to prepare the polymeric surface 108f for electroless deposition. In at least one implementation, the activation pretreatment process of operation 210 is preceded by a cleaning operation. The cleaning operation may begin with a cleaner-conditioner designed to remove organics and condition a plurality of circuit layers (or a circuit board) with one or more through-holes for the subsequent uptake of catalyst. The cleaner-conditioners may include an alkaline solution.

In at least one implementation, the activation process of operation 210 includes a pre-activation operation, an activation operation, and a post-activation operation. During the pre-activation operation, the polymeric surface 108f is exposed to a first bath, which usually contains hydrochloric acid and possibly sodium chloride. In at least one implementation, during the activation process of operation 210, the polymeric surface 108f is exposed to a catalyst bath that includes hydrochloric acid, tin chloride, and palladium chloride. The Sn⁺² ion reduces the Pd⁺² to Pd, which is deposited on the polymeric surface 108f. During the post-activation process of operation 210, the remaining Sn⁺² and Sn⁺⁴ are selectively removed by an accelerator (also called the post-activator). Suitable accelerators include fluoboric acid.

FIG. 3B illustrates a cross-sectional view of a portion of the structure 300 during intermediate stages of manufacturing corresponding to operation 220, in accordance with some implementations. During operation 220, optionally, the structure 300 is exposed to a heat treatment process. The heat treatment process of operation 220 is believed to improve adhesion of the subsequently deposited adhesion layer with the polymeric surface 108f. During operation 220, the structure 300 is exposed to heat at a temperature of 180 degrees Celsius or less, for example, a temperature in a range from about 100 degrees Celsius to about 180 degrees Celsius, or in a range from about 100 degrees Celsius to about 170 degrees Celsius, or in a range from about 100 degrees Celsius to about 150 degrees Celsius, or in a range from about 110 degrees Celsius to about 120 degrees Celsius. The heat treatment process of operation 220 may be performed for a time of 60 minutes or less, for example, a temperature in a range from about 30 second to about 30 minutes, or in a range from about 30 seconds to about 5 minutes, or in a range from about 1 minute to about 3 minutes. In one example, the heat treatment process is performed in a range from about 110 degrees Celsius to about 120 degrees Celsius for about 3 minutes.

FIG. 3C illustrates a cross-sectional view of a portion of the structure 300 intermediate stages of manufacturing corresponding to operation 230, in accordance with some implementations. During operation 230, an adhesion layer 310 is formed by an electroless deposition process. The adhesion layer 310 improves adhesion of the subsequently deposited copper seed layer to the polymeric surface 108f. The adhesion layer 310 may also function as a barrier layer by reducing the diffusion of subsequently deposited copper into underlying layers, for example, the insulating material 108. The adhesion layer 310 may be formed on the polymeric surface 108f as shown in FIG. 3C. In at least one implementation, the adhesion layer 310 contains a binary alloy or ternary alloy, for example, a binary or ternary cobalt or nickel alloy. Examples of ternary or binary cobalt or nickel alloys include cobalt boride (CoB), cobalt phosphide (CoP), nickel boride (NiB), nickel phosphide (NiP), cobalt tungsten phosphide (CoWP), cobalt tungsten boride (CoWB), nickel tungsten phosphide (NiWP), nickel tungsten boride (NiWB), cobalt molybdenum phosphide (CoMoP), cobalt molybdenum boride (CoMoB), nickel molybdenum phosphide (NiMoB), nickel molybdenum phosphide (NiMoP), nickel rhenium phosphide (NiReP), nickel rhenium boride (NiReB), cobalt rhenium boride (CoReB), cobalt rhenium phosphide (CoReP), derivatives thereof, or combinations thereof. In at least one particular implementation, the adhesion layer 310 includes NiP, NiWP, CoP, or CoWP. In at least one implementation, the adhesion layer 310 has a thickness “T₁” in a range from about 50 nanometers to about 500 nanometers, or in a range from about 100 nanometers to about 400 nanometers, or in a range from about 100 nanometers to about 300 nanometers, or in a range from about 240 nanometers to about 280 nanometers.

In at least one implementation, the structure 300 is subjected to one of two techniques for formation of the adhesion layer 310 on the polymeric surface 108f of the insulating material 108. The structure 300 can be dipped in a wet bath containing an electroless deposition solution or the structure 300 can be placed on a rotating chuck where the electroless deposition solution is injected on to the rotating wafer (technique of spin or shower deposition). The electroless deposition solution may be heated to a temperature in a range from about 70 degrees Celsius to about 100 degrees Celsius, or in a range from about 80 degrees Celsius to about 90 degrees Celsius, or in a range from about 80 degrees Celsius to about 85 degrees Celsius.

In at least one implementation where the adhesion layer 310 is NiP, the electroless deposition solution includes an aqueous nickel sulfate solution, an aqueous sodium hypophosphite solution, and DI water. In one example, the electroless deposition solution is formed by adding 5 ml of aqueous nickel sulfate solution and 10 mL of aqueous sodium hypophosphite solution to 85 ml of DI water.

After deposition of the adhesion layer 310 during operation 230, the adhesion layer 310 may be exposed to a heat treatment process at operation 235. The heat treatment process of operation 235 may be performed similarly to the heat treatment process of operation 220. The heat treatment process of operation 235 is believed to improve adhesion between the adhesion layer 310 and the polymeric surface 108f.

FIG. 3D illustrates a cross-sectional view of a portion of the structure 300 intermediate stages of manufacturing corresponding to operation 240, in accordance with some implementations. During operation 240, a copper seed layer 320, for example, an immersion copper seed layer, is formed by an immersion plating process. The immersion plating process deposits a copper coating on the adhesion layer 310 from a solution that contains copper. One metal in the adhesion layer 310 is displaced by a copper ion that has a lower oxidation potential than the displaced metal ion. In at least one implementation, the copper seed layer 320 displaces a portion of the adhesion layer 310, for example, 10% to 30% of T₁ is replaced by the copper seed layer 320 having a thickness “T₂” to reduce the thickness of the adhesion layer 310 from T₁ to “T₃”. In at least one implementation, the copper seed layer 320 has a thickness “T₂” in a range from about 10 nanometers to about 100 nanometers, or in a range from about 10 nanometers to about 50 nanometers, or in a range from about 40 nanometers to about 80 nanometers. In one example, the adhesion layer 310 has a thickness T₃ in a range from about 130 nanometers to 375 nanometers and the copper seed layer 320 has a thickness T₂ in a range from about 40 nanometers to about 80 nanometers.

In at least one implementation, the structure 300 is subjected to one of two techniques for formation of the copper seed layer 320 on the surface of the adhesion layer 310. The structure 300 can be dipped in a wet bath containing a contact displacement deposition solution (technique of immersion deposition) or the structure 300 can be placed on a rotating chuck where the contact displacement solution is injected on to the rotating wafer (technique of spin or shower deposition).

A variety of solutions acceptable for semiconductor use to permit copper atoms that form the copper seed layer 320 to adhere to the surface of the adhesion layer 310 by contact displacement can be used. In at least one implementation, the aqueous contact displacement solution is formed having deionized (DI) water as the main component of the solution. The various chemicals noted below may then be added to the DI water in quantities noted. The solution is further comprised of 0.001-2 mol/liter of Cu⁺² ions. The solution includes copper sulfate (CuSO₄) and sulfuric acid (H₂SO₄) to provide the copper ions. In at least another implementation, CuSO₄·5H₂O (1 g) and H₂SO₄ (2 ml to 5 ml) are added to 100 ml of DI water to form the aqueous contact displacement solution. In yet another implementation, CuSO₄·5H₂O (1 g) and H₂SO₄ (2 ml to 5 ml) and (NH₄)₂SO₄ (5 g) are added to 100 ml of DI water to form the aqueous contact displacement solution. The aqueous contact displacement solution may further include ammonium sulfate, for example, (NH₄)₂SO₄ (5 g). The exposed adhesion layer 310 is subjected to this solution for a time period of approximately 1-600 seconds, for example, 10-20 seconds at a temperature in the approximate range of 50 to 100 degrees Celsius, or in a range from about 80 to about 90 degrees Celsius, or in a range from about 85 to about 86 degrees Celsius. The parameters can be varied, but ultimately it is desirable to form the copper seed layer 320, having at least a monolayer of copper atoms to cover the surface of the adhesion layer 310. Then, the structure 300 is removed from the contact displacement solution and may be rinsed in DI water.

It is appreciated that by utilizing the above contact displacement process, the copper seed layer 320 is formed on the surface of the adhesion layer 310, so that now an auto-catalytic deposition of electrolessly deposited copper or electroplated copper can occur on the surface of the adhesion layer 310, once the structure 300 is placed in an copper electroplating solution or a copper electroless deposition solution. It is to be noted that the contact displacement technique is described in reference to the use of either cobalt-containing or nickel-containing adhesion layers, but the same contact displacement technique can be used with other adhesion layer materials as well to activate the surface of the adhesion layer for copper deposition.

After deposition of the copper seed layer 320 during operation 240, optionally, the copper seed layer 320 may be exposed to a heat treatment process at operation 245. The heat treatment process of operation 245 may be performed similarly to the heat treatment process of operation 220. The heat treatment process of operation 245 is believed to improve adhesion between the copper seed layer 320, the adhesion layer 310, and the polymeric surface 108f.

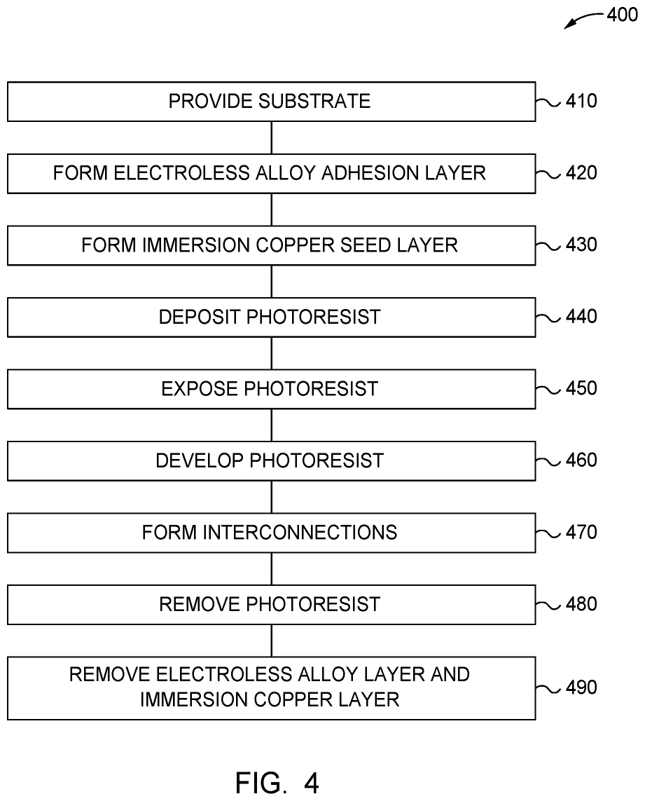

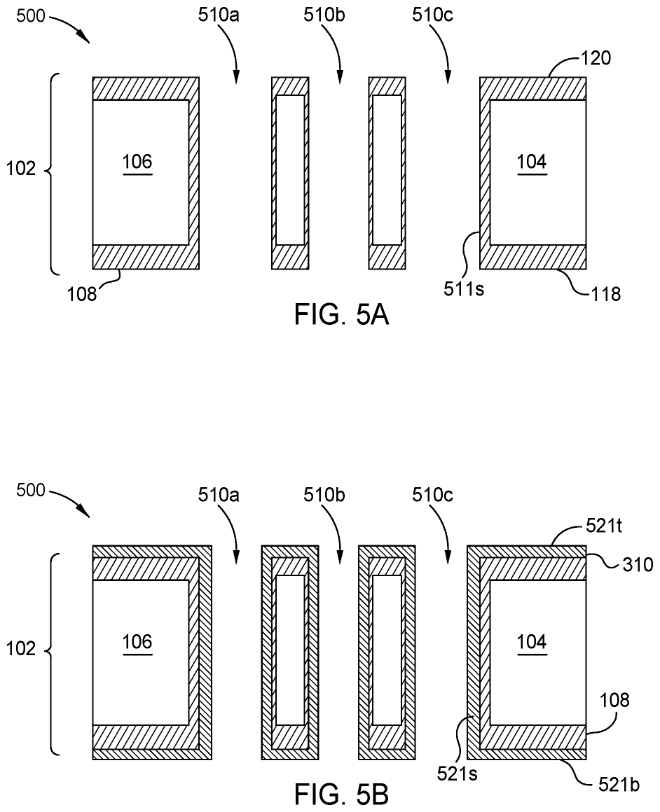

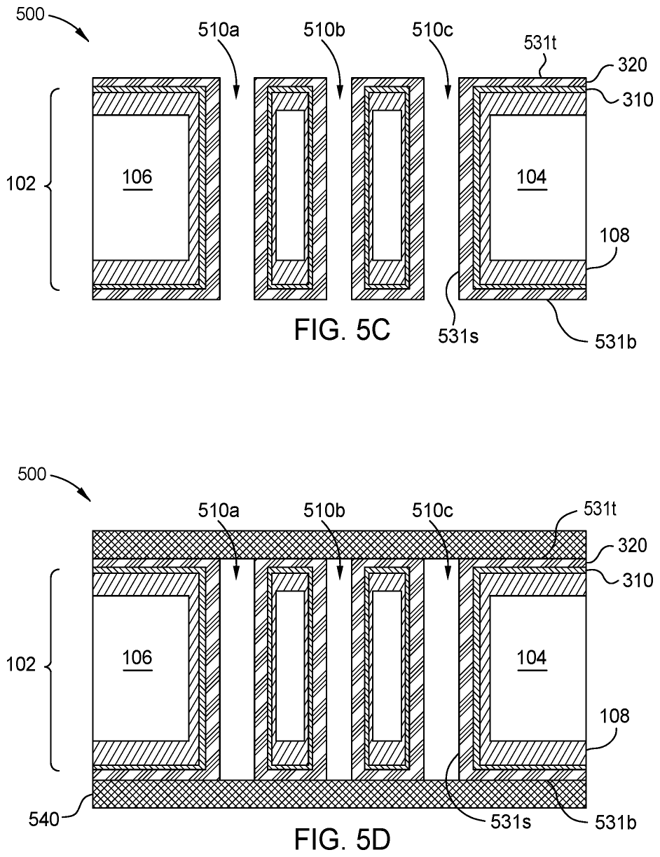

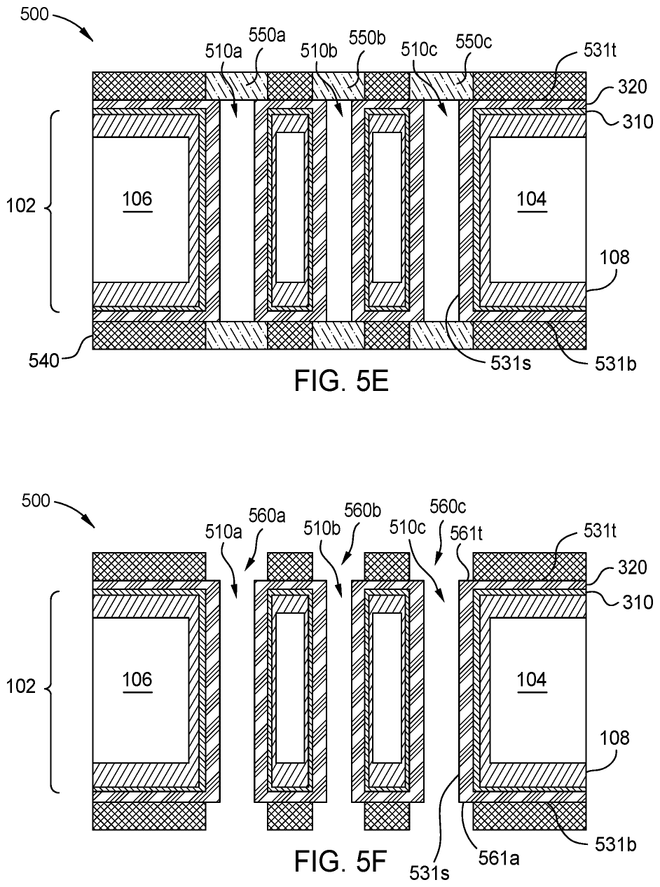

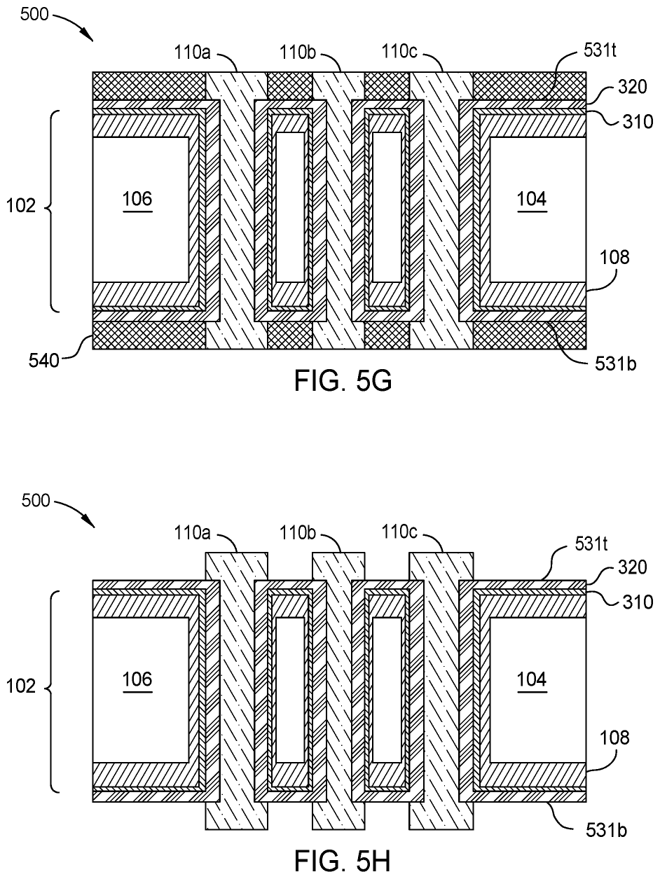

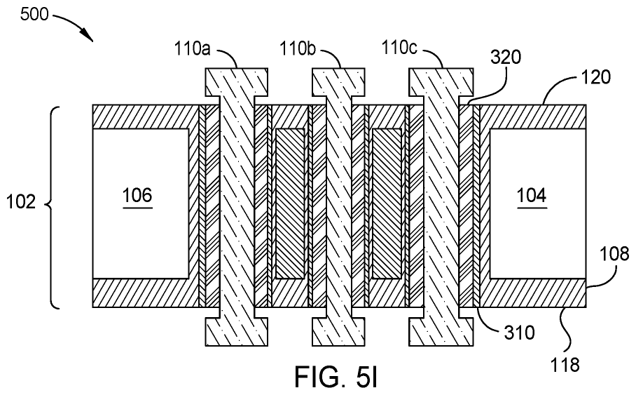

FIG. 4 illustrates an exemplary flow chart of a method 400 of forming a 3-D MCM structure in accordance with one or more implementations of the present disclosure. FIGS. 5A-5I illustrate cross-sectional views of various stages of forming a 3-D MCM structure in accordance with one or more implementations of the present disclosure. With reference to FIGS. 5A-5I, cross-sectional views of some implementations of a 3-D MCM structure at various stages of manufacture are provided to illustrate the method of FIG. 4. Although FIGS. 5A-5I are described in relation to the method 400, it will be appreciated that the structure disclosed in FIGS. 5A-5I are not limited to the method 400, but instead may stand alone as structures independent of the method 400. Similarly, although the method 400 is described in relation to FIGS. 5A-5I, it will be appreciated that the method 400 is not limited to the structures disclosed in FIGS. 5A-5I, but instead may stand alone independent of the structures disclosed in FIGS. 5A-5I.

FIG. 5A illustrates a cross-sectional view of a portion of a packaging structure 500 during intermediate stages of manufacturing corresponding to operation 410, in accordance with some implementations. The packaging structure 500 may form a portion of the 3-D MCM structure 100a, 100b. During operation 410, a substrate is provided, for example, the substrate 106 as shown in FIG. 4A. The substrate 106 has the insulating material 108 formed thereover. The insulating material 108 may be formed on all surfaces of the substrate 106 such that it surrounds the substrate 106. The insulating material 108 includes a sidewall 511s and the major surface 120 (also referred to as the top surface) and the major surface 118 (also referred to as the bottom surface). The packaging structure 500 includes one or more through-hole vias 510a-c extending the entire thickness of the substrate 106 and the insulating material 108. In one example, as depicted in FIG. 5A, three through-hole vias 510a-c are depicted. The through-hole vias 510a-c are utilized to receive interconnections 110. The through-hole vias 510a-c may be formed via any suitable patterning process. In at least one implementation, the through-hole vias 510a-c are formed via a laser ablation process. In some implementations, the substrate 106 is not present, and the method 400 is performed on the insulating material 108.

The through-hole vias 510a-c have a depth equal to the thickness of the substrate 106 and the thickness of the insulating material 108, thus forming holes on opposing surfaces of the substrate 106 and the insulating material 108. For example, the through-hole vias 510a-c formed in the substrate 106 may have a depth of between about 10 μm and about 1 mm, depending on the thickness of the substrate 106.

FIG. 5B illustrates a cross-sectional view of a portion of the packaging structure 500 during intermediate stages of manufacturing corresponding to operation 420, in accordance with some implementations. During operation 420, the adhesion layer 310 is formed. The adhesion layer 310 may be formed over all surfaces of the substrate 106 such that it surrounds the substrate 106. For example, as shown in FIG. 5B, the adhesion layer 310 is formed over the sidewalls 511s and the major surfaces 118 and 120 defined by the insulating material 108. The adhesion layer 310 includes a sidewall 521s and a top surface 521t and a bottom surface 521b. The sidewall 521s and the top surface 521t and the bottom surface 521b of the adhesion layer 310 may be parallel to or substantially parallel to the sidewall 511s and the major surface 120 (also referred to as the top surface) and the major surface 118 of the insulating material 108 respectively. As described, the adhesion layer 310 is formed by an electroless deposition process, for example, the techniques described in the method 200.

FIG. 5C illustrates a cross-sectional view of a portion of the packaging structure 500 during intermediate stages of manufacturing corresponding to operation 430, in accordance with some implementations. During operation 430, the copper seed layer 320 is formed. The copper seed layer 320 may be formed over all surfaces of the substrate 106 such that it surrounds the substrate 106. For example, as shown in FIG. 5C, the copper seed layer 320 is formed over the sidewalls 521s and the bottom surface 521b and the top surface 521t defined by the adhesion layer 310. The copper seed layer 320 includes a sidewall 531s, a top surface 531t, and a bottom surface 531b. The sidewall 531s, the top surface 531t, and the bottom surface 531b of the copper seed layer 320 may be parallel to or substantially parallel to the sidewall 521s, the top surface 521t, and the bottom surface 521b of the adhesion layer 310 respectively. As described, the copper seed layer 320 is formed by an immersion (displacement) plating process, for example, the techniques of the method 200.

FIG. 5D illustrates a cross-sectional view of a portion of the packaging structure 500 during intermediate stages of manufacturing corresponding to operation 440, in accordance with some implementations. During operation 440, a photoresist layer 540, such as a dry film photoresist, is formed. The photoresist layer 540 is formed on the top surface 531t and the bottom surface 531b of the copper seed layer 320. The photoresist layer 540 may be formed on the copper seed layer 320 using, for example, a lamination process or a spin coating process. The photoresist layer 540 may be formed to a thickness in a range from about 0.5 microns to about 10 microns, or in a range from about 0.5 microns to about 1 micron.

FIG. 5E illustrates a cross-sectional view of a portion of the packaging structure 500 during intermediate stages of manufacturing corresponding to operation 450, in accordance with some implementations. During operation 450, the photoresist layer 540 is patterned and exposed to form a pattern of exposed portions 550a-c. The pattern of exposed portions 550a-c of the photoresist layer 540 correspond to the through-hole vias 510a-c. The photoresist layer 540 may be patterned by exposing the photoresist layer 540 to an energy source, for example, a patterned light source such as an ultraviolet (UV) light source, to induce a chemical reaction, thus inducing a physical change and selectively remove either the exposed portion of the photoresist layer 540 or the unexposed portion of the photoresist layer 540, depending upon the targeted pattern.

FIG. 5F illustrates a cross-sectional view of a portion of the packaging structure 500 during intermediate stages of manufacturing corresponding to operation 460, in accordance with some implementations. During operation 460, a developer is applied to the exposed portions 550a-c of the photoresist layer 540 to remove the exposed portions 550a-c and form openings 560a-c. The openings 560a-c in the photoresist layer 540 expose the sidewall 531s of the copper seed layer 320 formed in the through-hole vias 510a-c. The openings 560a-c in the photoresist layer 540 may further expose a portion 561t of the top surface 531t of the copper seed layer 320, and a portion 561b of the bottom surface 531b of the copper seed layer 320.

FIG. 5G illustrates a cross-sectional view of a portion of the packaging structure 500 during intermediate stages of manufacturing corresponding to operation 470, in accordance with some implementations. During operation 470, one or more interconnections 110a-c are formed though the entire thickness of the semiconductor package 102. The one or more interconnections include one or more conductive materials, such as copper tungsten, or other conductive metals, and may be formed by electroplating, electroless plating, or the like. In at least one implementation, an electroplating process is used where the copper seed layer 320 and the photoresist layer 540 are submerged or immersed in an electroplating solution. The surface of the copper seed layer 320 is electrically connected to the negative side of an external DC power supply such that the copper seed layer 320 functions as the cathode in the electroplating process. A solid conductive anode, such as a copper anode, is also immersed in the solution and is attached to the positive side of the power supply. The atoms from the anode are dissolved into the solution, from which the cathode, for example, the copper seed layer 320, acquires the dissolved atoms, thus plating the exposed conductive areas of the copper seed layer 320 within the opening of the photoresist layer 540.

FIG. 5H illustrates a cross-sectional view of a portion of the packaging structure 500 during intermediate stages of manufacturing corresponding to operation 480, in accordance with some implementations. During operation 480, the photoresist layer 540 may be removed using a suitable removal process. In at least one implementation, a plasma ashing process is used to remove the photoresist layer 540, where the temperature of the photoresist may be increased until the photoresist experiences a thermal decomposition and may be removed. However, any other suitable process, such as a wet strip, may alternatively be utilized to remove the photoresist layer 540. The removal of the photoresist may expose the underlying portions of the copper seed layer 320, for example, the top surface 531t and the bottom surface 531b of the copper seed layer 320.

FIG. 5I illustrates a cross-sectional view of a portion of the packaging structure 500 during intermediate stages of manufacturing corresponding to operation 490, in accordance with some implementations. During operation 490, removal of the exposed portions of the copper seed layer 320 and the underlying adhesion layer 310 may be performed. Removal of the exposed portions of the copper seed layer 320 and the underlying adhesion layer 310 may expose the major surfaces 118 and 120 of the insulating material 108. In at least one implementation, the exposed portions of the copper seed layer 320 and underlying adhesion layer 310, for example, portions of the copper seed layer 320 and underlying adhesion layer 310 that are not covered by the one or more interconnects 110a-c may be removed by, for example, a wet or dry etching process. For example, in a dry etching process reactants may be directed towards the copper seed layer 320 and the underlying adhesion layer 310 using the one or more interconnects 110a-c as a mask. In another implementation, an etchant solution may be sprayed or otherwise put into contact with the copper seed layer 320 and the underlying adhesion layer 310 in order to remove the exposed portions of the copper seed layer 320 and the underlying adhesion layer 310.

In at least one implementation, the etchant solution includes copper sulfate, sulfuric acid, and DI water. The etchant solution may include from about 0.5 M to about 1.5 M CuSO₄·5H₂O and from about 0.02 M to 2 M H₂SO₄. In one example, the etchant solution includes 5 g of CuSO₄·H₂O, 2 mL of H₂SO₄, and 100 ml of water and the copper seed layer 320 and the adhesion layer 310 are exposed to the etchant solution for a period of 12 to 14 minutes. The etchant solution removes the copper seed layer 320 and the adhesion layer 310 at a greater rate than the copper of the interconnect 110a-c.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, or example of the present disclosure, or a particular claim, that feature can also be used, to the extent possible in combination with and/or in the context of other particular aspects and implementations of the present disclosure, and in the present disclosure generally.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

While the foregoing is directed to embodiments of the present disclosure, other and further embodiments of the disclosure may be devised without departing from the basic scope thereof, and the scope thereof is determined by the claims that follow.

What is claimed is:

1. A method of manufacturing a semiconductor device, comprising:
depositing an adhesion layer on a polymeric surface by an electroless deposition process, wherein the polymeric surface defines a sidewall of a through-hole via and the adhesion layer comprises a cobalt alloy or a nickel alloy;
depositing a copper seed layer on the adhesion layer by an immersion plating process, wherein the copper seed layer displaces a portion of the adhesion layer; and
filling the through-hole via with a copper containing layer.

2. The method of claim 1, further comprising exposing the polymeric surface to a heat treatment process prior to depositing the adhesion layer, wherein the heat treatment process comprises exposing the polymeric surface to heat at a temperature in a range from about 100 degrees Celsius to about 150 degrees Celsius.

3. The method of claim 2, further comprising exposing the polymeric surface to an activation process prior to the heat treatment process, comprising:
exposing the polymeric surface to a first bath comprising hydrochloric acid and sodium chloride;
exposing the polymeric surface to a catalyst bath comprising hydrochloric acid, tin chloride, and palladium chloride; and
exposing the polymeric surface to fluoboric acid.

4. The method of claim 1, wherein the electroless deposition process comprises exposing the polymeric surface to an electroless deposition solution comprising aqueous nickel sulfate solution, an aqueous sodium hypophosphite solution, and water.

5. The method of claim 4, wherein the electroless deposition solution is heated to a temperature in a range from about 80 degrees Celsius to about 90 degrees Celsius.

6. The method of claim 1, wherein the portion of the adhesion layer that is replaced by the copper seed layer is about 10 to about 30% of the original thickness of the adhesion layer.

7. The method of claim 1, wherein the adhesion layer comprises NiP, NiWP, CoP, or CoWP.

8. The method of claim 7, wherein the polymeric surface comprises polybenzoxazole (PBO), polyimide, a polyimide derivative, an epoxy resin, a prepreg (PP) material, or a combination thereof.

9. A method of manufacturing a semiconductor device, comprising:
providing a substrate comprising an insulating material, the insulating material defining a first major surface, a second major surface opposite the first major surface, and a through-hole via coupling the first major surface and the second major surface;
depositing an adhesion layer on the insulating material by an electroless deposition process, wherein the insulating material defines a sidewall of the through-hole via and the adhesion layer comprises a cobalt alloy or a nickel alloy;
depositing a copper seed layer on the adhesion layer by an immersion plating process, wherein the copper seed layer displaces a portion of the adhesion layer;
forming a photoresist layer on the copper seed layer formed over at least the first major surface;
patterning the photoresist to form an opening through the photoresist layer, wherein the opening exposes the copper seed layer formed along the sidewall of the through-hole vias; and
filling the through-hole via and the opening with a copper containing layer to form an interconnect structure.

10. The method of claim 9, further comprising removing the photoresist to expose the adhesion layer and the copper seed layer formed over at least the first major surface.

11. The method of claim 10, further comprising removing the adhesion layer and the copper seed layer from the first major surface by an etching process, wherein the etching process removes the copper seed layer and the adhesion layer at a greater rate than the copper of the interconnect structure.

12. The method of claim 11, wherein the etching process comprises exposing the adhesion layer and the copper seed layer to an etchant solution comprising copper sulfate and sulfuric acid.

13. The method of claim 11, wherein the etching process comprises exposing the adhesion layer and the copper seed layer to an etchant solution comprising from about 0.5 M to about 1.5 M CuSO₄·5H₂O and from about 0.02 M to 2 M H₂SO₄.

14. The method of claim 9, further comprising exposing the polymeric surface to a heat treatment process prior to depositing the adhesion layer, wherein the heat treatment process comprises exposing the polymeric surface to heat at a temperature in a range from about 100 degrees Celsius to about 150 degrees Celsius.

15. The method of claim 14, further comprising exposing the polymeric surface to an activation process prior to the heat treatment process, comprising:
exposing the polymeric surface to a first bath comprising hydrochloric acid and sodium chloride;
exposing the polymeric surface to a catalyst bath comprising hydrochloric acid, tin chloride, and palladium chloride; and
exposing the polymeric surface to fluoboric acid.

16. A semiconductor device, comprising:
a substrate comprising an insulating material, the insulating material defining a first major surface, a second major surface opposite the first major surface, and a through-hole via coupling the first major surface and the second major surface;
an adhesion layer formed on the insulating material defining a sidewall of the through-hole via, the adhesion layer comprising a cobalt alloy or a nickel alloy;
a copper seed layer formed on the adhesion layer; and
a copper interconnection extending the entire thickness of the substrate, the copper interconnection filling the through-hole via and extending passed both the first major surface and the second major surface.

17. The semiconductor device of claim 16, wherein the adhesion layer comprises NiP, NiWP, CoP, or CoWP.

18. The semiconductor device of claim 17, wherein the polymeric surface comprises polybenzoxazole (PBO), polyimide, a polyimide derivative, an epoxy resin, a prepreg (PP) material, or a combination thereof.

19. The semiconductor device of claim 18, wherein the substrate further comprises a semiconductor die encapsulated by the insulating material.

20. The semiconductor device of claim 19, wherein the substrate is part of a three-dimensional multichip module.
